(19) United States
(12) Patent Application Publication
(10) Pub. No.: US 2023/0282541 A1
(43) Pub. Date: Sep. 7, 2023

(54) SEMICONDUCTOR DEVICE

(71) Applicant: Mitsubishi Electric Corporation, Tokyo (JP)

(72) Inventors: Masayuki NISHIYAMA, Tokyo (JP); Naoki YOSHIMATSU, Tokyo (JP)

(73) Assignee: Mitsubishi Electric Corporation, Tokyo (JP)

(21) Appl. No.: 18/062,411

(22) Filed: Dec. 6, 2022

(30) Foreign Application Priority Data
Mar. 2, 2022 (JP) 2022-031382

(51) Int. Cl. H01L 23/367; H01L 23/31; H01L 23/495

(52) U.S. Cl. CPC H01L 23/3675; H01L 23/3135; H01L 23/3142; H01L 23/49568; H01L 24/48; H01L 2924/13055; H01L 2924/182

(57) ABSTRACT

A semiconductor device includes a heat dissipating component and a semiconductor module. The semiconductor module includes: a metal plate bonded to a bonded region on the upper surface of the heat dissipating component via a bonding material; an insulating layer disposed on an upper surface of the metal plate; a metal component disposed on an upper surface of the insulating layer; a semiconductor element disposed on an upper surface of the metal component; and a sealant sealing the metal plate, the insulating layer, the metal component, and the semiconductor element with a lower surface of the metal plate being exposed. The heat dissipating component includes a step formed around an outer periphery of the bonded region so that the outer periphery is lower than the bonded region, and a resin for protecting a bonded portion between the semiconductor module and the heat dissipating component is applied to the step.

### BACKGROUND OF THE INVENTION

### Field of the Invention

The present disclosure relates to a semiconductor device.

### Description of the Background Art

Japanese Patent Application Laid-Open No. 2012-142465 discloses a semiconductor device in which a metal plate exposed in a semiconductor module is bonded to a cooler (corresponding to a heat dissipating component) via a bonding material. In this semiconductor device, a non-bonded region of the metal plate, a region surrounding the bonding material, and a region around a bonded portion of the cooler are covered with a resin. This enhances the reliability of a bonded portion between the semiconductor module and the cooler.

The technology described in this Patent Application provides an anchor portion on the upper surface of the cooler to which the resin is applied, for enhancing adhesion with the resin. However, this technology has a problem of difficulty in applying the resin to a predetermined position in manufacturing the semiconductor device, because a bonded region and the non-bonded region on the upper surface of the cooler are of the same height.

The object of the present disclosure is to provide a technology that can facilitate applying, to a predetermined position, a resin for protecting a bonded portion between a semiconductor module and a heat dissipating component in manufacturing a semiconductor device.

### SUMMARY

The object of the present disclosure is to provide a technology that can facilitate applying, to a predetermined position, a resin for protecting a bonded portion between a semiconductor module and a heat dissipating component in manufacturing a semiconductor device.

A semiconductor device according to the present disclosure includes a heat dissipating component and a semiconductor module. The semiconductor module is disposed on an upper surface of the heat dissipating component. The semiconductor module includes a metal plate, an insulating layer, a metal component, a semiconductor element, and a sealant. The metal plate is bonded to a bonded region on the upper surface of the heat dissipating component via a bonding material. The insulating layer is disposed on an upper surface of the metal plate. The metal component is disposed on an upper surface of the insulating layer. The semiconductor element is disposed on an upper surface of the metal component. The sealant seals the metal plate, the insulating layer, the metal component, and the semiconductor element with a lower surface of the metal plate being exposed. The heat dissipating component includes a step formed around an outer periphery of the bonded region so that the outer periphery is lower than the bonded region. A resin for protecting a bonded portion between the semiconductor module and the heat dissipating component is applied to the step.

Since the step is formed so that the outer periphery of the bonded region of the heat dissipating component is lower than the bonded region, the space for applying the resin is increased. Furthermore, the step facilitates casting the resin into the outer periphery of the bonded region in the heat dissipating component. Thus, the resin can be easily applied at a predetermined position in manufacturing the semiconductor device.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a cross-sectional view of a semiconductor device according to Embodiment 1;

FIG. 2 is a cross-sectional view of a semiconductor device according to Embodiment 2;

FIG. 3 is a cross-sectional view of the semiconductor device according to a modification of Embodiment 2;

FIG. 4 is a cross-sectional view of a semiconductor device according to Embodiment 3;

FIG. 5 is a cross-sectional view of a semiconductor device according to Embodiment 4;

FIG. 6 is a cross-sectional view of a semiconductor device according to Modification 1 of Embodiment 4;

FIG. 7 is a cross-sectional view of a semiconductor device according to Modification 2 of Embodiment 4; and

FIG. 8 is a cross-sectional view of a semiconductor device according to Embodiment 5.

### DESCRIPTION OF THE PREFERRED EMBODIMENTS

### Embodiment 1

### [Structure of Semiconductor Device]

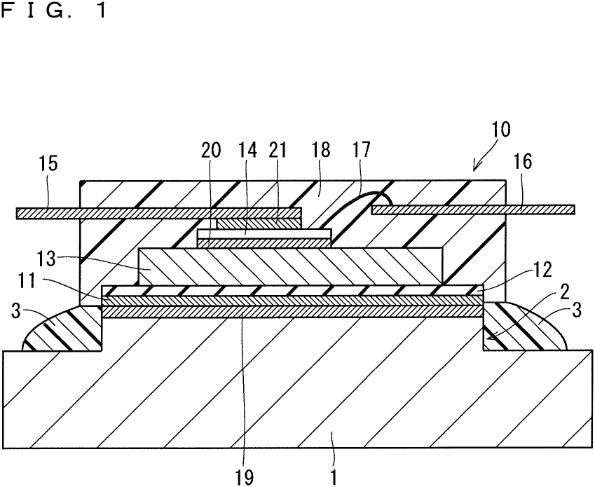

Hereinafter, Embodiment 1 will be described with reference to the accompanying drawing. FIG. 1 is a cross-sectional view of a semiconductor device according to Embodiment 1.

As illustrated in FIG. 1, the semiconductor device includes a semiconductor module 10 and a heat dissipating component 1. First, the semiconductor module 10 will be described.

The semiconductor module 10 is disposed on the upper surface of the heat dissipating component 1. The semiconductor module 10 includes a metal plate 11, an insulating layer 12, a metal component 13, a semiconductor element 14, a sealant 18, and lead electrodes 15 and 16.

The metal plate 11 is bonded to a bonded region on the upper surface of the heat dissipating component 1 via a bonding material 19. The metal plate 11 is copper foil of a thickness of 105 µm. Thinning the metal plate 11 by using a material of high thermal conductivity can improve the heat dissipation from the insulating layer 12 to the bonding material 19.

The insulating layer 12 is disposed on the upper surface of the metal plate 11. The insulating layer 12 can be made of a resin containing thermal conductive fillers and having thermal conductivity higher than or equal to 10 W/m·K. The use of the resin having high thermal conductivity and being deformation resistant in the insulating layer 12 can prevent cracks generated when, for example, the heat cycle infinitesimally deforms components of the semiconductor device. This can make high heat dissipation compatible with high reliability in the semiconductor device.

The material of the insulating layer 12 is not limited to such. One of AlN, Al₂O₃, and Si₃N₄ can be used as the material. The use of the material having high thermal conductivity in the insulating layer 12 can improve the heat dissipation from the metal component 13 to the metal plate 11 through the insulating layer 12. This can inhibit elevation of the temperature of the semiconductor device, and increase the longevity of the semiconductor device.

The metal component 13 is disposed on the upper surface of the insulating layer 12. Preferably, the metal component 13 is made of a material with high thermal conductivity, for example, a copper block of a thickness of 3 mm.

The semiconductor element 14 is disposed on the upper surface of the metal component 13 via a bonding material 20. A plurality of top electrodes (not illustrated) are disposed on the upper surface of the semiconductor element 14. One of the top electrodes of the semiconductor element 14 is connected to one end of the lead electrode 15 via a bonding material 21. The semiconductor module 10 should include at least the one semiconductor element 14. According to Embodiment 1, the semiconductor module 10 includes the one semiconductor element 14. The semiconductor element 14 contains SiC or Si as a semiconductor material, and is, for example, a reverse-conducting insulated gate bipolar transistor (RC-IGBT).

Another top electrode of the semiconductor element 14 is connected to one end of the lead electrode 16 via an interconnection 17. The interconnection 17 is, for example, aluminum wire or copper wire.

A copper frame of a thickness of 0.64 mm is used as each of the lead electrodes 15 and 16 which function as parts of an electrical circuit. The lead electrodes 15 and 16 may be any components through which the electricity passes, for example, aluminum wire. When the lead electrode 15 is aluminum wire, the bonding material 21 between the lead electrode 15 and the semiconductor element 14 is unnecessary.

The sealant 18 is a thermosetting resin that seals the metal plate 11, the insulating layer 12, the metal component 13, and the semiconductor element 14 with the lower surface of the metal plate 11 being exposed. The sealant 18 is an epoxy resin according to Embodiment 1. Furthermore, external connectors that are the other ends of the lead electrodes 15 and 16 are electrically connected to external devices of the semiconductor module 10. Thus, the external connectors are exposed without the sealant 18. The sealant 18 may be made of any material as long as it enhances the reliability of the semiconductor module 10, preferably, the one that can form the semiconductor module 10 by transfer molding.

Although the bonding materials 20 and 21 are solder, they may be, for example, silver paste with high thermal conductivity. The bonding material 19 functions as bonding the semiconductor module 10 to the heat dissipating component 1. The bonding material 19 is solder of a thickness of 150 µm according to Embodiment 1. The bonding material 19 may be any as long as it enhances the thermal conductivity. The bonding material 19 maybe, for example, thermal grease.

Next, the heat dissipating component 1 will be described. As illustrated in FIG. 1, the heat dissipating component 1 is formed into a block, and includes a step 2 formed around the outer periphery of the bonded region so that the outer periphery is lower than the bonded region. Preferably, the heat dissipating component 1 is made of a material that has high thermal conductivity and can be bonded via the bonding material 19. Preferably, the heat dissipating component 1 is made of, for example, copper, or nickel-plated aluminum. Since this enables the heat generated in the semiconductor module 10 to be efficiently dissipated, elevation of the temperature of the semiconductor module 10 can be inhibited.

Here, the bonded region is a region to which the metal plate 11 of the semiconductor module 10 is bonded, on the upper surface of the heat dissipating component 1, that is, a region to which the bonding material 19 is applied. Since the bonding material 19 is not applied to a region on the outer periphery of the bonded region on the upper surface of the heat dissipating component 1, this region is a non-bonded region. Hereinafter, the region on the outer periphery of the bonded region on the upper surface of the heat dissipating component 1 may be referred to as a “non-bonded region of the heat dissipating component 1”.

The step 2 is formed around the entire circumference of the upper surface of the heat dissipating component 1. In other words, the step 2 is formed to surround the bonded region of the heat dissipating component 1. A resin 3 for protecting the bonded portion between the semiconductor module 10 and the heat dissipating component 1 is applied to the step 2. Here, the bonded portion between the semiconductor module 10 and the heat dissipating component 1 is a portion including a region of the lower surface of the metal plate 11 which is in contact with the bonding material 19, the bonding material 19, and the bonded region on the upper surface of the heat dissipating component 1.

Although the resin 3 is an epoxy resin according to Embodiment 1, the resin 3 is not limited to such. The resin 3 may be any as long as it enhances the reliability of the bonding material 19 and allows the bonding material 19 to be cured at a temperature lower than or equal to a melting point. It is preferable that the resin 3 exhibits lower viscosity in consideration of the feature of filling necessary portions, and better adhesion with the sealant 18 and the heat dissipating component 1.

### [Advantages]

Next, advantages of the semiconductor device according to Embodiment 1 will be described in view of manufacturing processes. A semiconductor device is completed through processes of bonding the semiconductor module 10 to the heat dissipating component 1 via the bonding material 19 and then applying the resin 3 to the non-bonded region of the heat dissipating component 1 with the step 2.

When the heat dissipating component 1 does not include the step 2, a portion between the semiconductor module 10 and the heat dissipating component 1 to which the bonding material 19 is not applied has space as thick as the bonding material 19. Since the bonding material 19 has the thickness of 150 µm and the space is very low according to Embodiment 1, it has been difficult to cast the resin 3 into the space and apply the resin 3 to the space.

The semiconductor device according to Embodiment 1 includes the heat dissipating component 1, and the semiconductor module 10 disposed on the upper surface of the heat dissipating component 1. The semiconductor module 10 includes: the metal plate 11 bonded to a bonded region on the upper surface of the heat dissipating component 1 via a bonding material 19; the insulating layer 12 disposed on an upper surface of the metal plate 11; the metal component 13 disposed on an upper surface of the insulating layer 12; the semiconductor element 14 disposed on an upper surface of the metal component 13; and the sealant 18 sealing the metal plate 11, the insulating layer 12, the metal component 13, and the semiconductor element 14 with a lower surface of the metal plate 11 being exposed. The heat dissipating component 1 includes the step 2 formed around an outer periphery of the bonded region so that the outer periphery is lower than the bonded region, and the resin 3 for protecting a bonded portion between the semiconductor module 10 and the heat dissipating component 1 is applied to the step 2.

Since the step 2 is formed so that the outer periphery of the bonded region of the heat dissipating component 1 is lower than the bonded region, the space for applying the resin 3 is increased. Furthermore, the step 2 facilitates casting the resin 3 into the outer periphery of the bonded region in the heat dissipating component 1. Thus, the resin 3 can be easily applied at a predetermined position. Consequently, the semiconductor device can be easily manufactured.

Since not only the bonding material 19 but also the resin 3 can more firmly fix the semiconductor module 10 to the heat dissipating component 1, damage to the bonding material 19 and the insulating layer 12 which is caused by, for example, the heat cycle can be prevented. This can enhance the reliability of the semiconductor device.

Since the bonding material 19 contains thermal grease, the damage to the insulating layer 12 which is caused by, for example, the heat cycle can be further prevented. Since the resin 3 can more firmly fix the semiconductor module 10 to the heat dissipating component 1, the bonding material 19 in operating the semiconductor device can be prevented from being pumped out.

Since the bonding material 19 contains solder, the heat generated by the semiconductor module 10 can be effectively transferred to the heat dissipating component 1. This can inhibit elevation of the temperature of the semiconductor device, and enhance the reliability of the semiconductor device. Since fixing the semiconductor module 10 to the heat dissipating component 1 via the resin 3 can prevent the damage to the bonding material 19 which is caused by, for example, the heat cycle, the reliability of the semiconductor device can be enhanced.

The semiconductor element 14 contains SiC as a semiconductor material. Since SiC is probably used at high temperatures, warpage of the semiconductor module 10 greatly varies. This leads to a growing concern about decreasing reliability in the bonded portion between the semiconductor module 10 and the heat dissipating component 1. The bonding material 19 is more likely to have cracks when being solder, and is more likely to be pumped out when being thermal grease. Thus, suppressing the variations in warpage of the semiconductor module 10 can enhance the reliability of the semiconductor device.

Since the semiconductor element 14 is an RC-IGBT, the semiconductor module 10 can become denser. However, this increases the heat generated by the semiconductor module 10. Thus, the bonding material 19 is more likely to have cracks when being solder, and is more likely to be pumped out when being thermal grease. Since fixing the bonding material 19 by the resin 3 can prevent occurrence of such problems, the reliability of the semiconductor device can be enhanced.

Since the metal plate 11 contains copper, the heat generated by the semiconductor element 14 can be effectively transferred to the heat dissipating component 1. This can inhibit elevation of the temperature of the semiconductor device.

Since the metal component 13 contains copper, the heat generated by the semiconductor element 14 can be effectively transferred to the heat dissipating component 1. This can inhibit elevation of the temperature of the semiconductor device.

### Embodiment 2

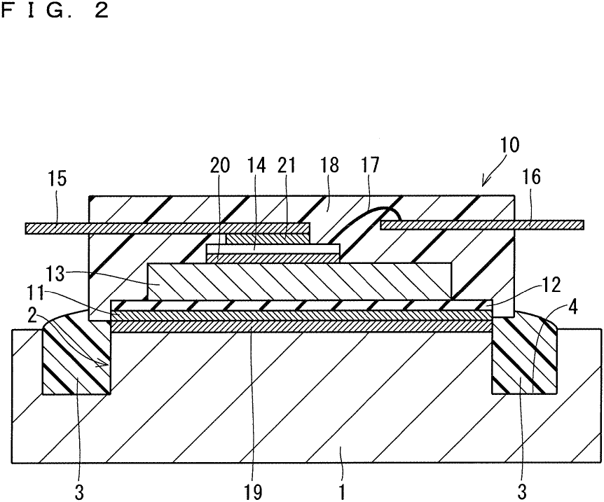

Next, a semiconductor device according to Embodiment 2 will be described. FIG. 2 is a cross-sectional view of the semiconductor device according to Embodiment 2. In Embodiment 2, the same reference numerals are assigned to the same constituent elements described in Embodiment 1, and the description thereof will be omitted.

As illustrated in FIG. 2, the step 2 according to Embodiment 1 is formed by a groove 4 according to Embodiment 2. The groove 4 is formed on the non-bonded region of the heat dissipating component 1 except an outer edge of the heat dissipating component 1. Furthermore, the groove 4 is formed around the entire circumference of the upper surface of the heat dissipating component 1 to surround the bonded region of the heat dissipating component 1.

Since the step 2 is formed by the groove 4 in the semiconductor device according to Embodiment 2, the resin 3 to be cured can be retained in the groove 4. This can manage the amount of the resin 3, and improve the productivity of the semiconductor device.

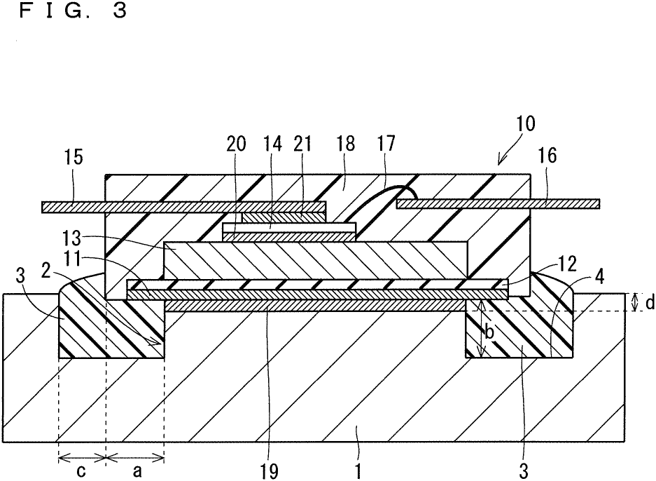

Next, a modification of Embodiment 2 will be described with reference to FIG. 3. FIG. 3 is a cross-sectional view of the semiconductor device according to the modification of Embodiment 2.

FIG. 3 specifies a preferred dimension of the groove 4 according to the modification of Embodiment 2. A distance “a” from the inner side surface of the groove 4 in the heat dissipating component 1 to the side surface of the semiconductor module 10 and a distance “b” from the bottom of the groove 4 in the heat dissipating component 1 to the lower surface of the semiconductor module 10 satisfy a relationship of a ≤ b. Here, the side surface of the semiconductor module 10 is the side surface of the sealant 18. The lower surface of the semiconductor module 10 is the lower surface of the metal plate 11. Since this structure facilitates the resin 3 flowing to the groove 4 immediately below the semiconductor module 10 in applying the resin 3, the productivity of the semiconductor device can be further improved.

A region on the outer periphery of the groove 4 on the upper surface of the heat dissipating component 1 is higher than the bonded region. Since this facilitates the resin 3 flowing to the semiconductor module 10 in applying the resin 3 and increases a contact area between the resin 3 and the semiconductor module 10, the semiconductor module 10 can be more firmly fixed to the heat dissipating component 1. This can enhance the reliability of the semiconductor device.

Furthermore, the distance “b” from the bottom of the groove 4 in the heat dissipating component 1 to the lower surface of the semiconductor module 10 and a distance “c” from the side surface of the semiconductor module 10 to the outer side surface of the groove 4 in the heat dissipating component 1 satisfy a relationship of b ≤ c. Only a part or the entire circumference of the groove 4 may satisfy the relationship of b ≤ c.

Since this can facilitate applying the resin 3, the productivity of the semiconductor device can be improved.

Furthermore, a difference “d” between the height of the region on the outer periphery of the groove 4 on the upper surface of the heat dissipating component 1 and the height of the bonded region on the upper surface of the heat dissipating component 1 is greater than the thickness of the bonding material 19. Since this increases the contact area between the resin 3 and the side surface of the semiconductor module 10 and the resin 3 adheres to the side surface of the semiconductor module 10, the semiconductor module 10 can be more firmly fixed to the heat dissipating component 1. This can enhance the reliability of the semiconductor device.

### Embodiment 3

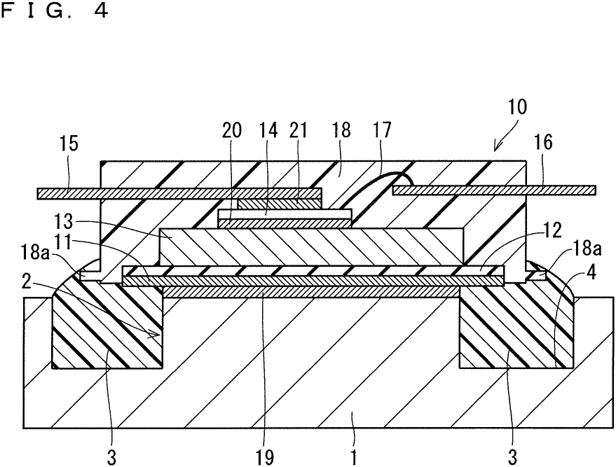

Next, a semiconductor device according to Embodiment 3 will be described. FIG. 4 is a cross-sectional view of the semiconductor device according to Embodiment 3. In Embodiment 3, the same reference numerals are assigned to the same constituent elements described in Embodiments 1 and 2, and the description thereof will be omitted.

As illustrated in FIG. 4, the semiconductor module 10 according to Embodiment 2 additionally includes, on the side surface, a plurality of protrusions 18a protruding laterally in Embodiment 3. The plurality of protrusions 18a are covered with the resin 3. The plurality of protrusions 18a are disposed on the side surface of the sealant 18. Since the resin 3 is cast between the protrusions 18a and the outer side surface of the groove 4 in the heat dissipating component 1 in applying the resin 3, the resin 3 can be easily applied at a predetermined position. The structure of Embodiment 3 is applicable to that of Embodiment 1.

The plurality of protrusions 18a increase the contact area between the semiconductor module 10 and the resin 3, and enhance adhesion between the resin 3 and the semiconductor module 10. This can more firmly fix the semiconductor module 10 to the heat dissipating component 1. Consequently, the reliability of the semiconductor device can be further enhanced.

The plurality of protrusions 18a are made of the material identical to that of the sealant 18. The protrusion 18a may be of any shape as long as it increases the surface area of the sealant 18, for example, a cube or a cylinder.

### Embodiment 4

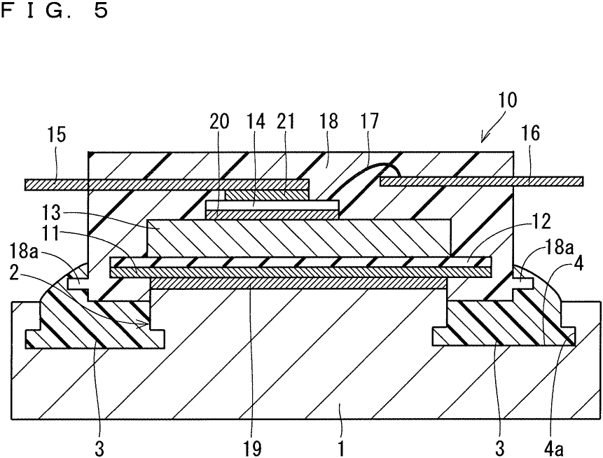

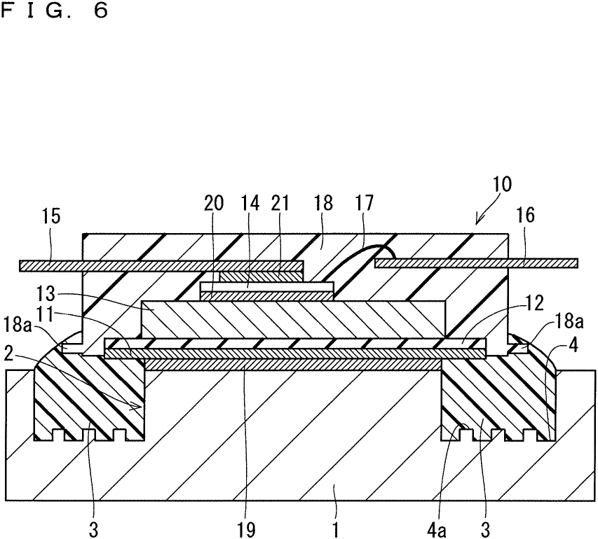

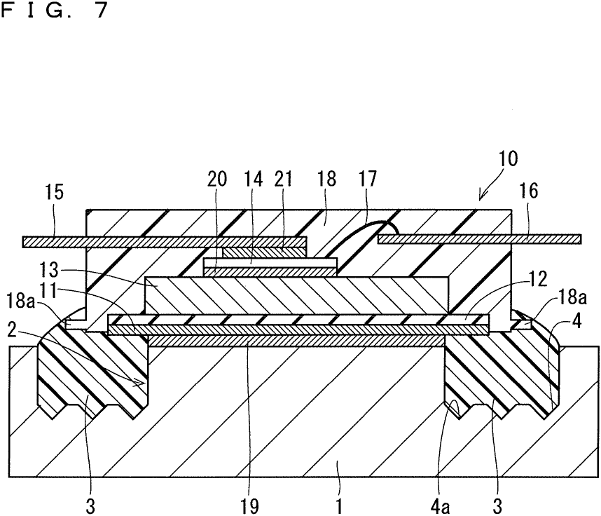

Next, a semiconductor device according to Embodiment 4 will be described. FIG. 5 is a cross-sectional view of the semiconductor device according to Embodiment 4. FIG. 6 is a cross-sectional view of the semiconductor device according to Modification 1 of Embodiment 4. FIG. 7 is a cross-sectional view of the semiconductor device according to Modification 2 of Embodiment 4. In Embodiment 4, the same reference numerals are assigned to the same constituent elements described in Embodiments 1 to 3, and the description thereof will be omitted.

As illustrated in FIG. 5, the step 2 according to Embodiment 3 additionally includes an undercut portion 4a in Embodiment 4. The undercut portion 4a is formed at the bottom of the groove 4 to extend to the inner periphery and the outer periphery of the groove 4. The structure of Embodiment 4 is applicable to those of Embodiments 1 and 2.

This can enhance adhesion between the resin 3 and the heat dissipating component 1, and more firmly fix the semiconductor module 10 to the heat dissipating component 1. Consequently, the reliability of the semiconductor device can be further enhanced.

The undercut portion 4a formed at the bottom of the groove 4 may be of any shape as long as it enhances adhesion between the resin 3 and the heat dissipating component 1, for example, rectangular irregularities in a cross-sectional view of FIG. 6, or triangular irregularities in a cross-sectional view of FIG. 7.

### Embodiment 5

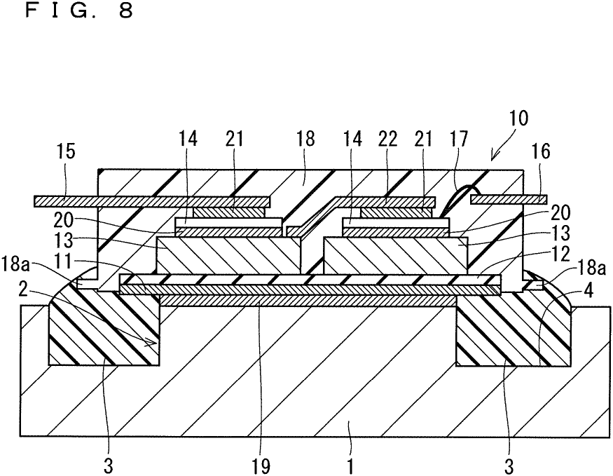

Next, a semiconductor device according to Embodiment 5 will be described. FIG. 8 is a cross-sectional view of the semiconductor device according to Embodiment 5. In Embodiment 5, the same reference numerals are assigned to the same constituent elements described in Embodiments 1 to 4, and the description thereof will be omitted.

As illustrated in FIG. 8, the semiconductor module 10 according to Embodiment 3 includes a plurality of (e.g., two) metal components 13 in Embodiment 5. The two connection relationships between the metal components 13 and the semiconductor elements 14 are the same. A top electrode of one of the semiconductor elements 14 (the left one in FIG. 8) is bonded to one end of the lead electrode 15 via the bonding material 21. A top electrode of the other semiconductor element 14 (the right one in FIG. 8) is bonded to one end of a lead electrode 22 via the bonding material 21. The upper surface of the metal component 13 on which the one of the semiconductor elements 14 is disposed is bonded to the other end of the lead electrode 22. Furthermore, the other semiconductor element 14 is connected to one end of the lead electrode 16 via the interconnection 17. The structure of Embodiment 5 is applicable to those of Embodiments 1 to 4.

The semiconductor module 10 including the plurality of metal components 13 has large variations in warpage due to change in the temperature. When compared to the semiconductor module 10 including the one metal component 13, the bonding material 19 is more likely to have cracks when being solder, and is more likely to be pumped out when being thermal grease. Since Embodiment 5 enables the semiconductor module 10 to be more firmly fixed to the heat dissipating component 1, the variations in warpage can be suppressed. This can enhance the reliability of the semiconductor device.

Embodiments can be freely combined, and appropriately modified or omitted.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device, comprising:
a heat dissipating component; and
a semiconductor module disposed on an upper surface of the heat dissipating component,
wherein the semiconductor module includes:
a metal plate bonded to a bonded region on the upper surface of the heat dissipating component via a bonding material;
an insulating layer disposed on an upper surface of the metal plate;
a metal component disposed on an upper surface of the insulating layer;
a semiconductor element disposed on an upper surface of the metal component; and
a sealant sealing the metal plate, the insulating layer, the metal component, and the semiconductor element with a lower surface of the metal plate being exposed,
the heat dissipating component includes a step formed around an outer periphery of the bonded region so that the outer periphery is lower than the bonded region, and
a resin for protecting a bonded portion between the semiconductor module and the heat dissipating component is applied to the step.

2. The semiconductor device according to claim 1,
wherein the bonding material contains thermal grease.

3. The semiconductor device according to claim 1,
wherein the bonding material contains solder.

4. The semiconductor device according to claim 1,
wherein the semiconductor module includes, on a side surface, a plurality of protrusions protruding laterally, and
the plurality of protrusions are covered with the resin.

5. The semiconductor device according to claim 1,
wherein the step is formed by a groove.

6. The semiconductor device according to claim 1,
wherein the step includes an undercut portion.

7. The semiconductor device according to claim 1,
wherein the semiconductor module includes a plurality of metal components including the metal component.

8. The semiconductor device according to claim 1,
wherein the semiconductor element contains SiC as a semiconductor material.

9. The semiconductor device according to claim 1,
wherein the semiconductor element is a reverse-conducting insulated gate bipolar transistor.

10. The semiconductor device according to claim 1,
wherein the metal plate contains copper.

11. The semiconductor device according to claim 1,
wherein the metal component contains copper.

12. The semiconductor device according to claim 5,
wherein a distance “a” from an inner side surface of the groove in the heat dissipating component to a side surface of the semiconductor module and a distance “b” from a bottom of the groove in the heat dissipating component to a lower surface of the semiconductor module satisfy a relationship of a ≤ b.

13. The semiconductor device according to claim 12,
wherein a region on an outer periphery of the groove on the upper surface of the heat dissipating component is higher than the bonded region.

14. The semiconductor device according to claim 13,
wherein a difference between a height of the region on the outer periphery of the groove on the upper surface of the heat dissipating component and a height of the bonded region on the upper surface of the heat dissipating component is greater than a thickness of the bonding material.

15. The semiconductor device according to claim 14,
wherein the distance “b” from the bottom of the groove in the heat dissipating component to the lower surface of the semiconductor module and a distance “c” from the side surface of the semiconductor module to an outer side surface of the groove of the heat dissipating component satisfy a relationship of b ≤ c.
